(19) United States
(12) Patent Application Publication
(10) Pub. No.: US 2004/0075466 A1
(43) Pub. Date: Apr. 22, 2004

(54) The trinary method for digital computing

(76) Inventor: Vishal Soral, State of Maharashira (IN)

Correspondence Address: THORPE NORTH & WESTERN, LLP., 8180 SOUTH 700 EAST, SUITE 200, P.O. BOX 1219, SANDY, UT, 84070, US

(21) Appl. No.: 10/273,435

(22) Filed: Oct. 17, 2002

(51) Int. Cl. H03K 19/02

(52) U.S. Cl. 326/59

(57) ABSTRACT

A trinary method of digital computing or data processing uses three states logically represented as 1, 0 and −1.

This invention relates to “Any Digital Electronic Device using Trinary Method of Digital Computing or Data Processing”.

The present invention relates to the field of Digital Electronics. Any or all digital electronic devices and Digital Computing Systems, like Logic Gates, memory circuits (whether discrete, or integrated on a chip), microprocessors, microcontrollers, and even quantum and molecular computers, which so far have been using Binary System, can be improved by using the present invention.

The object of this invention is to provide for improved devices and appliances, like Personal Computers, Supercomputers, embedded systems like automatic machines, which incorporate electronic devices that use Trinary method for Digital computing and data processing, as disclosed in the invention.

A digital computer is one of the most widely and popularly used electronic machine today. Currently, all digital computer systems, use, at the lowest level (i.e. at the chip level), a binary system. That is, the processor works with two discrete states, 0 and 1, which logically translates to FALSE and TRUE. Even the numbers are represented using the Binary System, i.e. all numbers are a represented as sequence of 0's and 1's.

In the recent years, many constant efforts have gone into improving the Binary System to make it most efficient and fast. However, the system has started hitting physical limitations, making it more difficult to improvise upon with the existing methods.

The hardware of the digital computer is designed to understand only two states, which in the currently used Binary System, are represented electronically by a ‘low voltage’ and a ‘higher voltage’.

In all existing digital systems, the Binary number system is used as the underlying layer. This is implemented electronically, by representing the two logic states 0 and 1 by electrical voltages 0 V/5V or +15 V. The logic states 1 and 0 are representatives of TRUE and FALSE or YES and NO. The binary system deals with only these states. The way these states are use in a digital system may be expressed in the following way

In any digital system with control input, if the control input is at state 1, i.e. TRUE or YES, it allows a particular action, while if the control input is at state 0, or NO, it disallows or prohibits a particular action. This means that in general, any control signal shall either mean GO or would mean STOP, which leads to a possibility (and perhaps a need) of a third state, something meaning neither YES nor NO.

In binary system, suppose we have a situation like the one illustrated by the circuit in FIG. 1 (see figures)

The Control line functions as follows: If the control line is at Binary level ‘0’, the AND gate is disabled. While if it is at binary level ‘1’, the OR gate output is set to binary state ‘1’. In binary system the Control line can have only the two aforesaid states. This means that under no circumstance shall, for the given circuit, the two inputs, Input-l and Input-2, independently control the corresponding outputs (output-I and output-2), simultaneously.

The present invention enhances the capability of such a system by enabling the control line such that, for one state of Control line, only the AND Gate getting affected; for second state, only the OR Gate . . . and providing another state, a THIRD one for which, the Control line would relinquish control, i.e. would not affect either of the gates

The Trianry System:

Any assembly of digital electronic devices which individually use a Trinary Method for representation of logic states and numbers, is to be referred to as a Trinary System. Henceforth, all references to a Trinary System, shall mean a system comprising of such electronic devices and components which use Trinary Method.

The Trinary Sequence:

In binary system, the numbers are represented as sequence of 0's and 1's. Mathematically the base is 2, as illustrated

000=0×2²+0×2¹+0×2⁰=0

001=0×2²+0×2¹+1×2⁰=1

010=0×2²+1×2¹+0×2⁰=2

011=0×2²+1×2¹+1×2⁰=3

. . . and so on. And as we know, these states are represented, electronically, by ±15 Volts or 0/5 Volts, depending on the factors like fabrication technology and application. In a trinary system, the base (obviously) will be 3. So one of the ways of writing the number sequence will be as illustrated below:

000=0×3²+0×3¹+0×3⁰=0

001=0×3²+0×3¹+1×3⁰=1

002=0×3²+0×3¹+2×3⁰=2

010=0×3²+1×3¹+0×3⁰=3

. . . and so on.

In this case, however, it is difficult to represent the three basic states 0, 1 and 2, electronically. This can be done if we represent the three digital states, using three different levels, for example we could use [0V, 5V, 10V]. But this kind of a system may not be so convenient to design and may not be strictly digital. We may however think of some other way to represent trinary numbers. Can we? The answer is—YES. If we recollect the fact that electrical current and voltage are vector quantities, we shall find a possible solution. In fact digital electronic devices, have so far not really exploited this aspect of electrical current/voltage.

In the present invention, the three states have been represented as: 0, 1 and −1? Consequently, the sequence will be:

000=0×3²+0×3¹+0×3⁰=0+0+0=0

001=0×3²+0×3¹+1×3⁰=0+0+1=1

01−1=0×3²+1×3¹+−1×3⁰=0+3−1=2

010=0×3²+1×3¹+0×3⁰=0+3+0=3

011=0×3²+1×3¹+1×3⁰=0+3+1=4

1−1−1=1×3²+−1×3¹+−1×3⁰=9−3−1=5

1−10=1×3²+−1×3¹+0×3⁰=9−3+0=6

We shall note that a trinary number series is a sequence of −1 0 1. This illustrated in the table below:

TABLE I
Illustrating the Trinary Series

| Binary Series | | | | | Trinary Series | | | | |
|---|---|---|---|---|---|---|---|---|---|
| | | | | Decimal | | | | | Decimal |
| Sequence | | | | Equivalent | Sequence | | | | Equivalent |
| 0 | 0 | 0 | 0 | 0 | 0 | 0 | −1 | −1 | −4 |
| 0 | 0 | 0 | 1 | 1 | 0 | 0 | −1 | 0 | −3 |
| 0 | 0 | 1 | 0 | 2 | 0 | 0 | −1 | 1 | −2 |
| 0 | 0 | 1 | 1 | 3 | 0 | 0 | 0 | −1 | −1 |
| 0 | 1 | 0 | 0 | 4 | 0 | 0 | 0 | 0 | 0 |
| 0 | 1 | 0 | 1 | 5 | 0 | 0 | 0 | 1 | 1 |
| 0 | 1 | 1 | 0 | 6 | 0 | 0 | 1 | −1 | 2 |
| 0 | 1 | 1 | 1 | 7 | 0 | 0 | 1 | 0 | 3 |
| 1 | 0 | 0 | 0 | 8 | 0 | 0 | 1 | 1 | 4 |

Now this representation of a base-3 series can be implemented electronically by three levels, i.e. −V, 0, +V. [This is the implication of what was mentioned earlier; that electrical current and voltage are vector quantities. This means that in contrast to a binary system, where only the magnitude of electrical signals is utilized to distinguish between two binary states, in which magnitude and direction are used to represent three distinct states. So we have

Trinary −1 Voltage with negative polarity (−V volts) or, current in reverse direction.

Trinary 0 No current/voltage (0 volts)

Trinary +1 Voltage with positive polarity (+V volts) or, current in forward direction. [image] The preliminary arithmetic of converting a decimal number into a trinary number brings out an interesting property of such a number system. We observe on comparing the trinary equivalents of 14 and −14 that each ‘1’ is changed to ‘−1’ and vice-versa. In a binary system, a binary number of n digits could represent 2ⁿ numbers, ranging from 0 to 2ⁿ−1. The equivalent figure in a trinary system is 3ⁿ, which has been explained below:

For two digits: range is −1−1 to 1 1 i.e. from −4 to +4, including 0 (total 9 numbers, which is 3²)

For three digits: range is −1−1−1 to 1 1 1 i.e. from −13 to +13 including 0 (total 27 numbers, which is 3³)

So for n digits, the range is from

$$\frac{- ( {3}^{n} - 1 )}{2} to \frac{+ ( {3}^{n} - 1 )}{2} including 0$$

(total 3ⁿ numbers).

The trinary system presents the following advantages over the binary system:

For a given number of digits, a trinary system will represent more decimal numbers than a binary number. For example a three bit binary number can represent numbers from 0 to 7 while a three digit trinary number can represent numbers from −13 to +13. The difference is significant as we increase the number of digits. Lets consider a byte, the corresponding figures (for 8 digits) are 256 (0 to 255)₂ and 6561 (−3280 to +3280)₃.

Representation of negative numbers is more straightforward and direct. As compared to binary system where a sign bit is required, in a trinary system just reversing the sign of all 1's and −1's can do the job. In other words, trinary numbers are implicitly signed.

The third state adds a new degree of freedom to the system. That is, in addition to the states YES and NO, we have a third ‘Don't Care’ or ‘Neutral’ state.

The Trinary Arithmetic:

The basic arithmetic of trinary numbers, as discussed earlier, described decimal-trinary conversion and back. Before we proceed any further, it is appropriate now to pause and discuss a little more on trinary arithmetic, specifically addition and subtraction of trinary digits. And so in brief—

| | | | | | |
|---|---|---|---|---|---|
| 0 + 0 = 0 | carry 0 | 1 + 0 = 1 | carry 0 | −1 + 0 = −1 | carry 0 |
| 0 + 1 = 1 | carry 0 | 1 + −1 = 0 | carry 0 | −1 + 1 = 0 | carry 0 |
| 0 + −1 = −1 | carry 0 | 1 + 1 = −1 | carry 1 | −1 + −1 = 1 | carry −1 |

And to be a bit more a ppropriate, we need to discuss only t he addition of trinary digits, a separate discussion of subtraction is not needed since the trinary numbers are implicitly signed.

Trinary Logic:

This section describes the building blocks of a trinary system vis-a-vis the NOT gate, the AND gate and the OR gate.

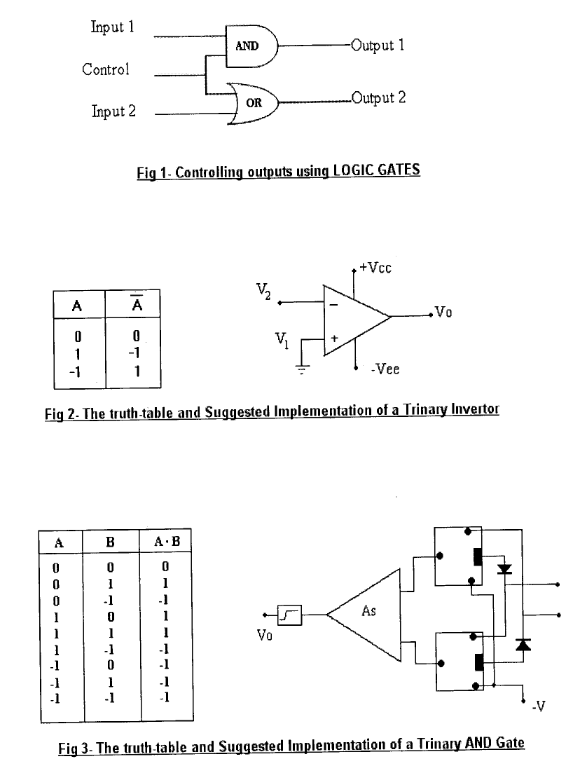

THE TRINARY INVERTER [NOT Gate]: The truth table for a trinary inverter or a NOT gate (the terms to be used interchangeably), is shown in the table along with FIG-2 (see figures). Note that in a trinary system, the state 0 is a NEUTRAL state. Therefore its inversion is the same. In logical terms, the state ‘0’, which represents ‘Neither YES nor NO’, when inverted would be ‘Neither NO nor YES’ which logically is the same. The other states i.e. 1 and −1 when inverted would be −1 and 1 respectively. (I believe it makes sense). The circuit shown in FIG. 2, is a suggested implementation of a trinary NOT gate, using a dual supply differential amplifier. Recall that for such a circuit, the output voltage Vₒ, for the two input voltages V₁ and V₂, is given by the relation:

| | | |
|---|---|---|
| | V₀ = −A(V₁ − V₂) | |
| => | V₀ = −V₂ | if −A = 1 and V₁ = 0. |
| => | V₀ = −Vᵢₙ | where Vᵢₙ = V₂ |

The output for such a circuit would then be as illustrated in the table shown in FIG-2

THE TRINARY AND GATE: The way a trinary AND operation has been defined is based on the binary AND gate. The difference is the presence of the third (Neutral) state i.e. 0. In a binary AND gate, the output is HIGH or 1 only if all the inputs are HIGH. If any input is LOW or 0, the output is LOW. The truth table for a two-input Trinary AND gate is shown in the table of FIG. 3

As can be seen from table (see figures), the output of the gate is −1 wherever any or both inputs are −1. However, when one of the inputs is 0, we observe that the output is simply same as the other input. This means that the state 0 is relinquishing control. If any state is at state 0, the output of the gate totally depends upon the other input. [This is the essence of three-state logic].

The circuit shown in FIG. 3, is a ‘possible’ implementation of a Trinary AND Gate, which is discussed in more detail later. To benefit from the familiarity with the binary convention, the AND operation is represented with a dot (A•B).

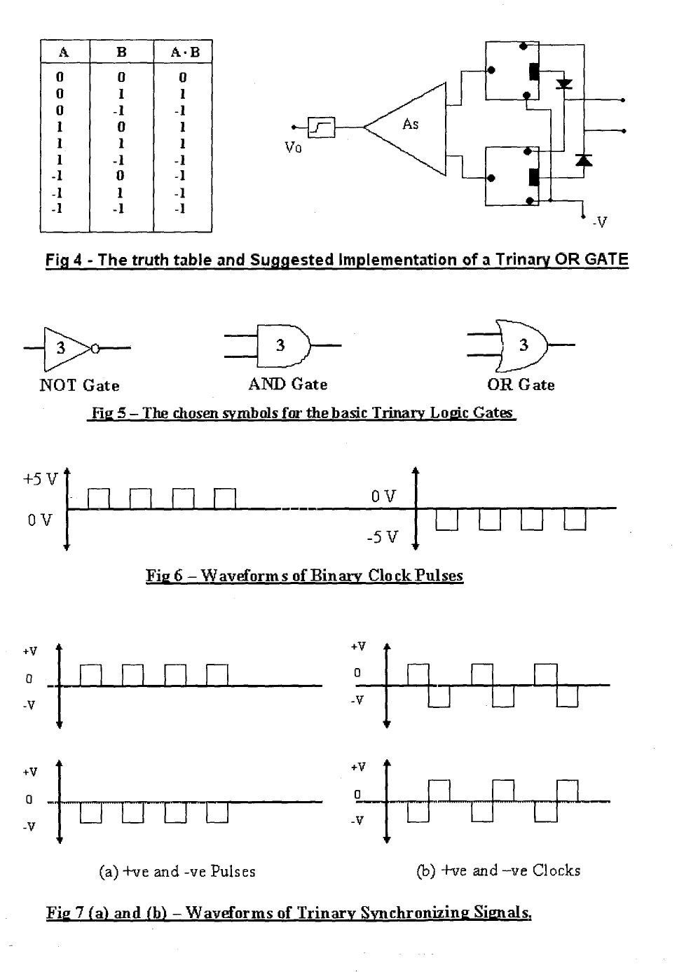

THE TRINARY OR GATE: The trinary OR gate has also been defined based on the binary OR gate. The output is LOW only if all the inputs are LOW. If any one of the inputs is HIGH, the output is HIGH. The third state or the Neutral state plays the same role as in the AND gate. The truth table for a two-input Trinary OR Gate is shown in the table of FIG. 4 (see figures).

It can be seen that the output is 1 wherever any one of the inputs is at 1. The circuit shown in FIG. 4, is a possible implementation of a trinary OR gate. (Discussed in more detail later). Again, for the sake of familiarity, the notation for an OR operation is (A+B).

FIG. 5 (see figures) shows symbols for the basic logic gates. The binary NOT, AND and OR gate symbols, with letter ‘3’ inside. These were considered appropriate since they retain the familiarity with the corresponding symbols in binary systems.

The discussion so far lays the foundation for a new approach towards digital computers. Let's look at a few more interesting facts before we move to advanced topics.

If we define the AND, OR and NOT operations as above, and represent these operations as A^{·}B, A+B and \overline{A} respectively, then, the following identities hold good:

| | |
|---|---|
| A + B = B + A | A + (B + C) = (A + B) + C |
| A · B = B · A | A · (B · C) = (A · B) · C |
| A + 0 = A | A · 0 = A |
| A + 1 = 1 | A · −1 = −1 |
| A + A = A | A · A = A |
| = | |
| A = A | |
| and provided (A ≠ 0) | |
| A + −1 = A | A · 1 = A |

All these identities can be verified, working according to the truth tables of the AND, OR and NOT gates as shown in FIGS. 3, 4 and 5 respectively.

There are, however, a few identities in binary which do not hold good in a trinary system, but this should be expected since we are working in trinary system which ought to have some differences. In fact, as the subject is explored further, it may be possible to establish a few new identities in a trinary system.

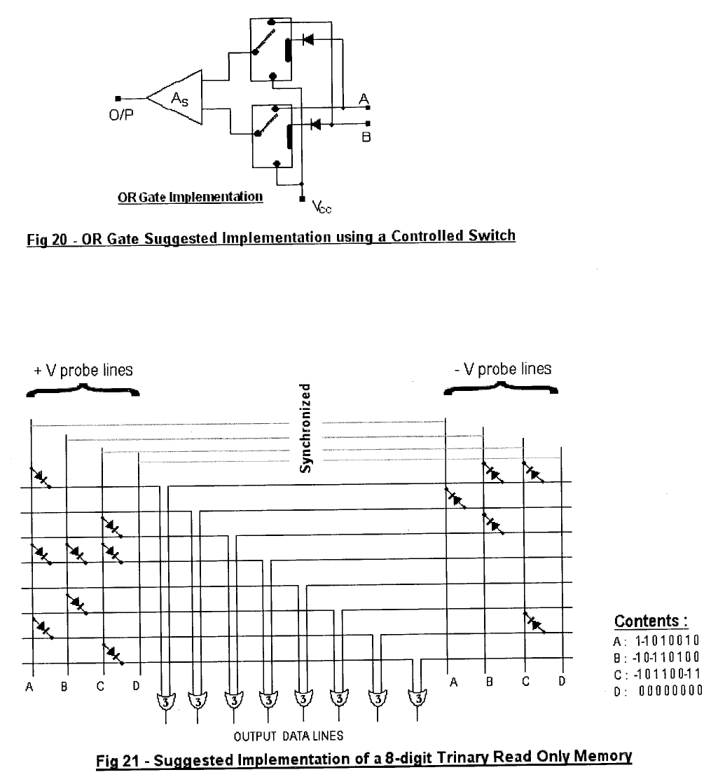

The Trinary AND Gate: The way a trinary AND Gate has been implemented is based on the Truth table shown in FIG. 3. FIG. 19 shows a suggested circuit diagram in more detail. The circuit consists of a Summing Amplifier and an Electrically Controlled Switch. FIG. 19 describes the Controlled Switch. It is similar to an electromagnetic relay that connects to the other pole of the switch when an electrical voltage of EITHER POLARITY is applied at its control input. The switch reverts back to the first pole when the control voltage is removed.

It might be possible to implement such a control switch using semiconductors in more than one ways. The actual semiconductor based implementation has not been discussed. We look at the working of the AND Gate. There are two such switches used in the AND Gate. The output of the switch is applied to a dual-supply Summing amplifier. The diodes connected at the control inputs ensure that the switches can be controlled using only a voltage of Negative Polarity. The voltage—V_{EE} is considered as logic level ‘−1’.

When both A and B are at ‘0’ state, the inputs to the Summing amplifier are 0 and 0 since none of the control switches is energized. Consequently, the output is 0.

When A is at level ‘0’, while B is at level ‘1’, the inputs to Aₛ are 0 and 1. Here again, none of the control switches is energized. The output is the sum of 0 and 1 that is 1.

When A is at level ‘0’while B is at level −‘1’, the lower control switch gets energized, causing the inputs to the Summing Amplifier to be −1 and −1. The output now becomes −1. [This being a digital system, any voltage level higher than 1 or lower than −1 in magnitude, is logically considered at 1 or −1 only. This can be further achieved by using a Voltage Clipper at the output].

When A and B both are at 1, the inputs to Aₛ are 1 and 1. The output is 1. [None of the control switches gets activated].

When A and B both are at −1, the inputs to A, are −1 and −1, the output being −1. [Both switches get energized].

When A is at level 1 and B is at level −1, the lower control switch is energized. The inputs to summing amplifier are −1 and −1. The output of Aₛ is −1.

All other combinations of A and B work similarly because of symmetry.

The Trinary OR Gate: The circuit diagram of a trinary OR Gate is almost similar to that of the AND gate, except that the fixed voltage o f negative polarity, −V_{EE} is replaced by a voltage of positive polarity, +V_{cc} and the diode polarities are reversed. The circuit is shown in FIG. 20. The working is analogous to the AND Gate.

Trinary Data and Signals:

Having already explored the basic arithmetical and logical operations with trinary numbers, the ways of representing trinary data and signals, has been discussed below. Specifically we shall look into a trinary digit-storing element, the Trinary Digital to Analog converter, Trinary toggle elements and counters, and Shift Registers. We shall also look into the synchronizing signals in a trinary system. Before we proceed, however, it need be emphasized, that most of the development (preceding as well as subsequent) discussed in this document is based on an unprecedented choice of logic and design. This is so because development was aimed at exploring a possibility of having a more efficient system.

Trinary Clock and Pulse System:

In a binary system a voltage level alternately switching between HIGH and LOW levels at some regular period, forms a clock or a synchronizing pulse. These could be of two types depending on whether a positive or a negative level is being used. FIG. 6 (see figures), illustrates the clock pulses in a binary system:

In a trinary system, things are different, owing to the existence of three states. The possible signals we can have in a trinary system are of four types: We can definitely have the above two types of pulses since a trinary system has provision for both positive and negative voltages. We respectively refer to them as positive and negative pulses. FIG. 7(a) (see figures) shows the positive and negative trinary pulses.

In a binary system, the pulse or a ‘Clock’ is an alternate switching between the two binary levels i.e. 0 and 1. Analogous to that, there could be a trinary clock which is a sequential toggle between its three states. FIG. 7(b) (see figures), shows the two possible trinary clock pulses. To start with there are four possible synchronizing signals in a trinary system. For the sake of convention we shall refer to them distinctly as +ve pulse, −ve pulse, +ve clock and −ve clock. [Again notice that in a binary system, the terms clock and pulse are not ‘strictly’ differentiated. In a trinary system it has only been chosen so, albeit arbitrarily, to use these names for clearly identifying the signals].

A Trinary Digit Storing Cell:

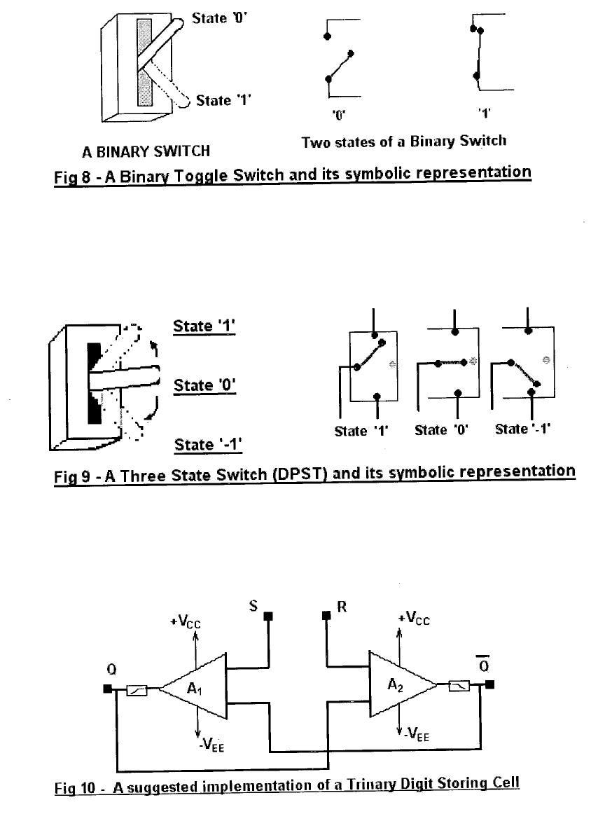

Analogous to a binary flip-flop, we need to have a device that stores a trinary digit. A binary Flip-flop is like a toggle or a ‘Single Throw Single Pole’ (SPST) switch as shown in FIG. 8 (see figures). Throwing the switch down is equivalent to storing a ‘1’, while throwing it up is equivalent to storing a ‘0’. If we now draw an analogy and think of a trinary cell as a ‘Double Pole Single Throw’ (DPST) switch as illustrated in FIG. 9 (see figues), then throwing up is equivalent of storing a ‘1’ while throwing down is equivalent of storing a ‘−1’. When the switch is in the central position, it is equivalent of storing ‘0’.

The following discussion elaborates the idea of the nature of inputs required to change the states of the trinary cell. Considering the DPST switch

If the DPST switch is initially at central position, a throw (force) towards either end shall take it from ‘0’ to either ‘1’ or ‘−1’, depending upon the direction of force. The duration for which the force is applied doesn't matter because on either sides of the middle position there is only one state. (i.e. the switch cannot acquire any state beyond 1 or −1, even if the force is continued to be applied].

If the switch is initially, say in ‘up’ position, and a throw (force) is applied downward, it shall come to central position i.e. from ‘1’ to ‘0’. However if the force is continued further it shall take the switch further down to state ‘−1’. In other words, when attempting to change the state from ‘1’ to ‘0’, the duration of force is important. [The situation is similar when trying to go from ‘−1’ to ‘0’]. This did not matter in former case (or in binary switches). Whereas in latter case, there exists a stable state of either sides of the ‘0’ state and a continuous force shall take the switch to that state. [The practical significance of this shall be discussed shortly].

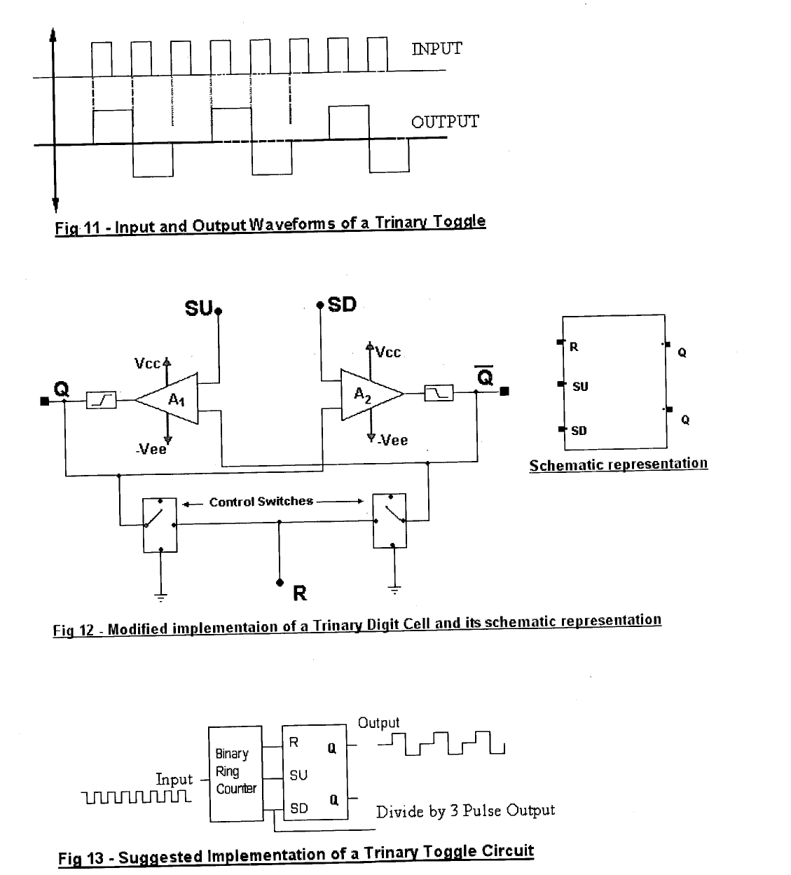

This concept is extended to develop a possible circuit which should store a trinary digit. In other words, a circuit for a ‘tri-stable multivibrator’. A suggested circuit as shown in FIG. 10 (see figures), has been developed on the principles of a binary flip-flop. The circuit works on the principle of regenerative feedback. It comprises of two dual supply differential amplifiers. The circuit can have three stable output states.

The truth table is shown in Table 2.1. The table shows all six possible combinations vis-a-vis SETing the cell to ‘1’ state from states ‘0’ and ‘−1’; RESETing the cell to ‘−1’ from states ‘0’ and ‘1’; and seting the cell to store a NEUTRAL state from states ‘1’ and ‘−1’. In the truth table, the term +Spike means a short duration pulse in the positive direction, with its time duration less than the net propagation delay between the output of one differential amplifier to the input of the other. The circuit shown above is equivalent of an SR-binary flip-flop. This however has more options- meaning that apart from the input states, as shown in table 2.1, there can be another set of input states. For instance, the output obtained by setting the input S to ‘1’ and R to ‘0’, can also be obtained by setting input R to ‘−1’ and S to ‘0’.

TABLE 2.1
Truth-Table for a Trinary Digit Storing Cell

| S | R | Q | \overline{Q} | Remark |
|---|---|---|---|---|
| 0 | 0 | 0 | 0 | Initial |
| 1 | 0 | 1 | −1 | Set |
| 0 | 0 | 1 | −1 | Stores 1; Set from 0 |
| 0 | 1 | −1 | 1 | Reset |
| 0 | 0 | −1 | 1 | Stores −1; Reset from 1 |
| 0 | 0 | 1 | −1 | Initial state |
| 0 | +Spike | 0 | 0 | Stores 0 |
| 0 | 0 | 0 | 0 | Neutral from 1 |
| 0 | 0 | −1 | 1 | Initial state |
| +Spike | 0 | 0 | 0 | Stores 0 |
| 0 | 0 | 0 | 0 | Neutral from −1 |
| 0 | 0 | 0 | 0 | Initial state |
| 0 | 1 | −1 | 1 | Stores −1 |
| 0 | 0 | −1 | 1 | Reset from 0 |
| 0 | 0 | −1 | 1 | Initial state |
| 1 | 0 | 1 | −1 | Stores 1 |
| 0 | 0 | 1 | −1 | Set from −1 |

This means that in order to store ‘1’, we either apply ‘1’ at SET or apply ‘−1’ at RESET (latter can be logically translated to mean don't RESET, or simply, SET).

The analogy can be extended further and indeed it is seen that same results can be obtained if a ‘1’ at S is replaced by ‘−1’ at R; a ‘1’ at R is replaced by ‘−1’ at S; a +Spike at R is replaced by a −Spike at S.

Trinary Toggle and Counters:

A trinary Toggle is a modification of the trinary digit cell, discussed above. The output of toggle switches between states −1, 0 and 1 in rotation, when a pulse is applied at its input. (The pulse refers to the waveform shown in FIG. 7).

The input and output waveforms are shown in FIG. 11 (see figures).

It can be seen from the figure that in a toggle, the output changes at every rising edge of the pulse. To implement such a circuit, we first need to modify the trinary digit-storing cell as discussed earlier. The modified circuit has been shown in FIG. 12 (see figures). The modified trinary digit-storing cell now has three inputs. The cell stores a ‘1’ for a positive pulse at input SU, a ‘−1’ for a positive pulse at SD, and a ‘0’ for a positive pulse at R. This circuit can now be used to develop a trinary toggle, the output of which shall be as shown in FIG. 11, for a pulse input. A suggested implementation has been shown in FIG. 13 (see figures). The circuit uses a binary ‘Ring-Counter’, followed by the Trinary Digit Cell.

The three-bit binary ring counter is connected such that each bit output forms a corresponding input to the Modified Trinary Digit Cell. In this circuit the positive pulse drives the Ring Counter and at each pulse, the three outputs of the Ring Counter, which are the inputs to the trinary toggle, is at state ‘1’, whereby the output Q, acquires states ‘0’, ‘1’ and ‘−1’ by rotation.

TABLE 2.2
Truth-Table for Trinary Toggle

| R | SU | SD | Q |
|---|---|---|---|
| 1 | 0 | 0 | 0 |
| 0 | 1 | 0 | 1 |
| 0 | 0 | 1 | −1 |

The circuit shown in FIG. 13 shall form the basic building block for counters and Shift Registers.

Counters:

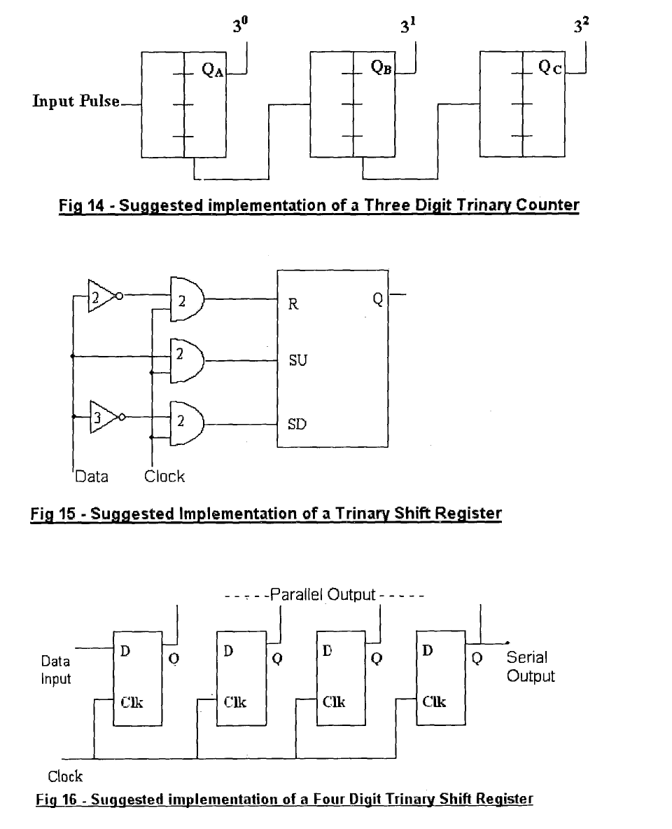

A trinary counter can be developed in a fashion similar to a binary counter, by cascading more than one trinary toggle units. The circuit implementation is shown in FIG. 14 (see figures). The Pulse O/P of preceding stage forms the Pulse I/P for the next stage.

Shift Registers:

Trinary Shift Registers can be constructed using the trinary toggle element along with a few logic gates. The circuit shown in FIG. 15 (see figures), is a suggested implementation. The circuit requires three binary AND gates, a binary INVERTOR and a Trinary INVERTOR.

The working can be briefly summed up thus: When ‘data’ is at 1, the binary AND gates at R and SD are disabled; only SU is enabled and at the clock pulse, the SU input becomes 1, setting the output Q to be 1.

When ‘data’ line is at 0, both SD and SU are disabled and on a clock pulse, R becomes 1, setting the output Q to be 0.

When ‘data’ line is at −1, only the AND gate at SD is enabled and a clock pulse sets the output Q to be −1. [Note that the clock-pulse referred above is the trinary pulse, not the trinary clock]. Now cascading several such element, so that the output Q of preceding stage is connected to the Data Input of the next stage, and connecting all Clock lines in synchronous manner, we can get an ‘n’ digit synchronous ‘Serial Input’ shift registers, as shown in FIG. 16 (see figures).

From the discussion of the Shift Register, it can be seen that even in trinary circuit elements, we need binary gates. This is because (as mentioned in Part 1), trinary system is not a complete replacement for binary system. It is an improvement over its predecessor. There still exist situations where a binary decision making is required.

Digital to Analog Conversion:

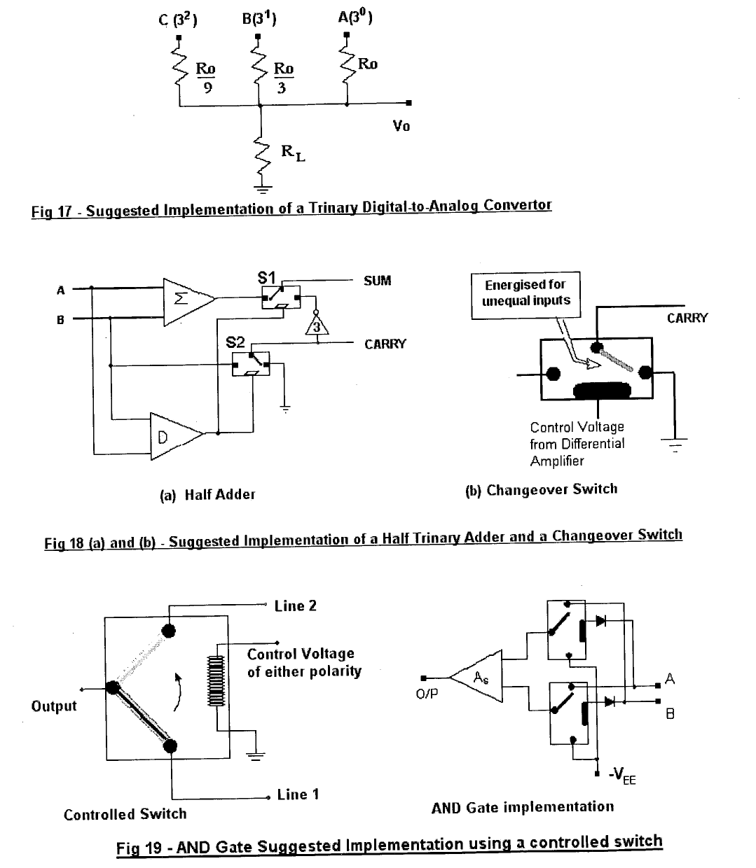

The D/A conversion in trinary system is much more similar to that in binary system. A Variable Resistive Network works in an analogous way. The values of the resistors are chosen in the ratios of powers of 3. FIG. 17 (see figures), shows a three digit trinary D/A converter, using the Resistive Network.

The output is an analog equivalent of the digital input assuming that R_{L}>>R_{O}. The digital states (for three digit network) are electrically represented by:

0=0V

+1=3⁰+3¹+3²=13 V

−1=−13 V

The input and corresponding output values have been summarized in table 2.3 below. The detailed circuit analysis has been omitted since it can be done easily using conventional Circuit Theories.

TABLE 2.3
Input-Output for a Trinary D/A Converter

| Digital Input | | | Equivalent Voltage | | | Analog |
|---|---|---|---|---|---|---|
| C | B | A | V₂ | V₁ | V₀ | Output |
| 0 | −1 | 1 | 0 V | −13 V | +13 V | −2 V |
| 0 | 0 | −1 | 0 V | 0 V | −13 V | −1 V |
| 0 | 0 | 0 | 0 V | 0 V | 0 V | 0 V |
| 0 | 0 | 1 | 0 V | 0 V | +13 V | 1 V |
| 0 | 1 | −1 | 0 V | +13 V | −13 V | 2 V |
| 0 | 1 | 0 | 0 V | +13 V | 0 V | 3 V |
| 0 | 1 | 1 | 0 V | +13 V | +13 V | 4 V |
| 1 | −1 | −1 | +13 V | −13 V | −13 V | 5 V |
| 1 | −1 | 0 | +13 V | −13 V | 0 V | 6 V |
| 1 | −1 | 1 | +13 V | −13 V | +13 V | 7 V |
| 1 | 0 | −1 | +13 V | 0 V | −13 V | 8 V |

Considering the analogies between binary and trinary systems, we can safely conclude that it should be possible to design an A/D converter, in a manner analogous to a binary A/D converter. A detailed discussion has therefore not been included.

Trinary Adders: The basic arithmetic of the numbers, has been repeated below in Table 2.4. We can now proceed towards implementing an adding circuit.

TABLE 2.4
Trinary Addition

| A | B | Sum | Carry |
|---|---|---|---|
| 0 | 0 | 0 | 0 |
| 0 | 1 | 1 | 0 |
| 0 | −1 | −1 | 0 |
| 1 | 1 | −1 | 1 |
| −1 | −1 | 1 | −1 |
| 1 | −1 | 0 | 0 |

Table 2.4 shows the six possible combinations in which two trinary digits can be added, and the resulting Sum digit and the Carry digit. FIG. 18 (see figures) shows a suggested implementation for a trinary adder. The circuit is a Half-adder, i.e. it does not incorporate the carry digit from the previous digit addition.

The Half-adder circuit has been implemented using a Summing amplifier, a difference amplifier, a trinary inverter, a and two changeover switches, (the ones discussed in part one, in context with the AND/OR gates). Whenever the input voltages (A and B) are unequal, there is a non-zero output at the difference amplifier (D). This keeps the switches, S1 and S2, energized. Switch S1 is then connected to output of the summing amplifier, while S2 connects to 0V(ground). The ‘Carry’ is 0, while the ‘Sum’ is as per table 2.4, depending upon the inputs. When the two inputs are equal, the output of the difference amplifier (D) becomes 0, and the switches S1 and S2, revert back to non-energized state thereby making the ‘Carry’ same as either of the inputs (S2 connects to one of the inputs), while the ‘Sum’ is the inversion of ‘Carry’ (S1 connects to output of the trinary inverter).

FIG. 18(b), (see figures), shows a magnified view of the changeover switch. The switch is energized for unequal inputs, meaning that unless the two input digits are same (i.e. either both inputs are +1 or −1), the output of difference amplifier is either +1 or −1, which activates both the switches. However as a special case when both inputs are 0, the output of difference amplifier is also 0, the switches are not energized but in that case, the Carry and Sum are also 0.

Trinary Read Only Memory:

Another major component of any computer system is the memory. The most basic kind being a ‘Read Only Memory’ has been discussed below. FIG. 21 (see figures), shows the suggested implementation of a Trinary ROM having four addressable locations, each containing an 8-digit data.

It is evident from the figure that the implementation is an extension of the Binary ROM. The diode matrix on the left side is exactly similar to a binary ROM. This matrix is for storing the positive part of trinary data, i.e. +1 or 0. The matrix on the right side has essentially analogous function except for that it stores the negative part of the data, vis-a-vis −1 and 0. The outputs of the two matrices are combined using trinary OR gates.

The horizontal lines in the matrix are the data lines. The vertical lines are the probe lines. The probe lines on the two sides are synchronized, i.e. line A on left matrix probes with a positive voltage at the same instance as the line A on the right matrix probes the matrix with a negative voltage. So in order to read the first memory location, a positive voltage (+V) is applied at line A on the left and simultaneously, a negative voltage (−V) is applied to line A on the right. The data is available at the output lines.

The advantages of which can be summarized thus:

1. Data Compression—One binary digit can represent at most two numbers. A trinary Digit will have capacity for one more. Extend this to more digits and the capacity increases exponentially. For example a three bit binary number can represent numbers from 0 to 7 while a three digit trinary number can represent numbers from −13 to +13. The difference is significant as we increase the number of digits. Lets consider a byte, the corresponding figures (for 8 digits) are 256 (0 to 255)₂ and 6561 (−3280 to +3280)₃. Conversely, this translates to implicit data-compression, since more data can now be represented using fewer digits.

2. Direct representation of negative numbers—As compared to binary system where a sign bit is required to represent negative number, in a trinary system just reversing the sign of all 1's and −1's can do the job. The benefit of course is due to the choice of design, i.e. representing the third state by −1.

3. Flexibility in Logic Design—The third state adds a new degree of freedom to the system. That is, in addition to the binary YES and NO, Trinary Method gives us a third state, a ‘Don't Care’ state giving a definite advantage to the designer of a digital computing system.

4. Moreover—The above advantages come with a relative ease of development, because trinary method, in theory does not impose any critical design restrictions on either the theoretical implementations or the fabrication techniques.

1) Any Digital electronic device using Trinary Method of Digital Computing or Data Processing, where the electronic device or computer system using such a method shall use three states logically represented as: 1, 0 and −1.

2) Any Digital electronic device using Trinary Method of Digital Computing as claimed in claim 1, fabricated using existing semiconductor techniques, or using molecular electronic technology or quantum-computer technology, where the trinary states for a semiconductor technology are represented using the electrical currents and voltages, and for molecular and Quantum technologies, the three states can be represented using any three stable states of the elements used for fabrication.

3) A Trinary Method of Digital Computing as claimed in claim 1, which utilizes the direction attribute of the electrical current and voltage to represent this new third state, i.e. −1 so that the three states of 0, 1, and −1 can be physically represented by NO CURRENT; CURRENT IN ONE DIRECTION and CURRENT IN REVERSE DIRECTION respectively.

4) A Trinary Method of Digital Computing as claimed in claim 1, which can theoretically operate within voltage range −V to 0 to +V volts, and practically from −220 to 0 to +220 volts or any voltage range falling within this, depending upon fabrication techniques, and/or application.

5) A Trinary Method of Digital Computing as claimed in claim 1, where the basic logic operations namely AND OR and NOT operations have been re-defined, and corresponding circuit schematic designed.

6) A Trinary Method of Digital Computing as claimed in claim 1, where a distinction has been established between a digital pulse and a digital clock signal, and where a digital clock gets another dimension due to the third state.

7) A Trinary Method of Digital Computing as claimed in claim 1, where other building blocks of a digital computational system, vis-a-vis the digit storing cell, the trinary counter, the trinary Shift Register, the trinary Digital-to-Analog convertor, the trinary Read-Only-Memory, the trinary half adder have been schematically designed.

8) A Trinary Method of Digital Computing which can be extended and enhanced to develop a Decimal Method for Digital Communication.
